(19) United States
(12) Patent Application Publication
(10) Pub. No.: US 2025/0364412 A1
(43) Pub. Date: Nov. 27, 2025

(54) STRUCTURE FOR SELF-ALIGNED VIA AND METHOD FOR FORMING THE SAME

(71) Applicant: Taiwan Semiconductor Manufacturing Company, Ltd., Hsinchu (TW)

(72) Inventors: Chih-Hao CHEN, Hsinchu (TW); Chung Chuan HUANG, Hsinchu (TW); Jian-Jou LIAN, Hsinchu (TW); Ching-Chun CHANG, Hsinchu (TW); Ming-Shuoh LIANG, Hsinchu (TW); Jye-Yen CHENG, Hsinchu (TW); Huan-Just LIN, Hsinchu (TW)

(73) Assignee: Taiwan Semiconductor Manufacturing Company, Ltd., Hsinchu (TW)

(21) Appl. No.: 18/674,743

(22) Filed: May 24, 2024

(51) Int. Cl. H01L 23/528; H01L 21/311; H01L 21/768

(52) U.S. Cl. CPC H01L 23/5283; H01L 21/31111; H01L 21/76804; H01L 21/76832

(57) ABSTRACT

A method of manufacturing a semiconductor device includes providing a semiconductor substrate layer including a metal interconnect feature embedded in the semiconductor substrate layer and depositing a liner layer on the metal interconnect feature. The method further includes depositing an etching stop layer on the liner layer and the semiconductor substrate layer and forming a dielectric layer on the etching stop layer with a via trench to expose the etching stop layer. The method also includes etching the etching stop layer and the liner layer to form a via structure to expose the metal interconnect feature, wherein the via structure has an hourglass-shaped profile.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is forming a via or hole through certain layers to line with an underlying electrically conductive layer, such that electrical conductivity between the layers is provided.

However, as miniaturization reaches a certain level, previously relatively simple processes have become increasingly complex. Pitch shrinkage is a significant method of miniaturization, but it poses many challenges such as thinner isolation space and increased concerns about leakage. As such, advances in the field of forming a bottom self-aligned via are necessary to reduce contact resistance and prevent leakage due to small isolation space, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIGS. 2A, 2B, and 2C show sectional views and a top view of a process stage of a sequential operation according to embodiments of the disclosure.

FIGS. 3A and 3B show sectional views of a process stage of a sequential operation according to embodiments of the disclosure.

FIGS. 4A and 4B show sectional views of a process stage of a sequential operation according to embodiments of the disclosure.

FIGS. 5A and 5B show sectional views of a process stage of a sequential operation according to embodiments of the disclosure.

FIGS. 6A and 6B show sectional views of a process stage of a sequential operation according to embodiments of the disclosure.

FIGS. 7A and 7B show sectional views of a process stage of a sequential operation according to embodiments of the disclosure.

FIGS. 8A, 8B, and 8C show sectional views and a top view of a process stage of a sequential operation according to embodiments of the disclosure.

FIGS. 9A, 9B, 10, 11A, 11B, 12A, and 12B illustrate examples of the bottom self-aligned vias according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Traditionally, current leakage between the via layer and the metal layer caused by small isolation spacing is controlled by precise critical dimension (CD) control for both the lithography and the etching process. However, unavoidable variations of the critical dimension uniformity, overlay, and stability also contribute to the leakage between the via layer and the metal layer. In some examples, to reduce via contact resistance, the via is oval-shaped in the leak non-critical direction. However, due to the variations of the critical dimension uniformity, overlay, and stability, as well as lithography dimensional constraints, the process window is insufficient to maintain the leakage margin and meet low contact resistance requirements. Embodiments of this disclosure provide an improved via structure and methods of forming the same, thereby reducing the contact resistance and preventing the leakage. For example, a bottom self-aligned Via (BSAV) structure may align the via bottom to the underlying metal interconnect layer in a dual damascene process and architecture, such that the via bottom critical dimension may be aligned with the critical dimension of the underlying metal interconnect layer.

In some embodiments of the present disclosure self-aligned dual damascene vias are formed. It will be understood by those skilled in the art that the disclosure could be applied to the formation of other structures, including dual damascene structures that don't serve as via openings between metal layers.

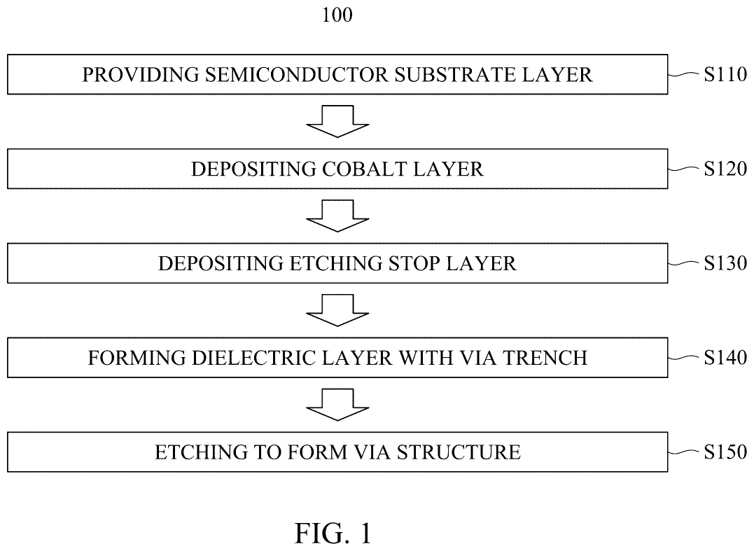

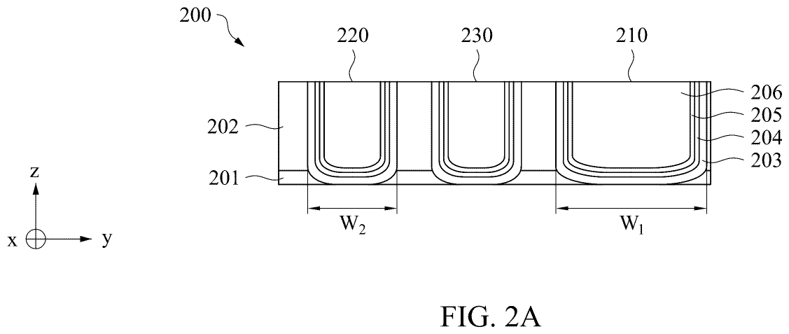

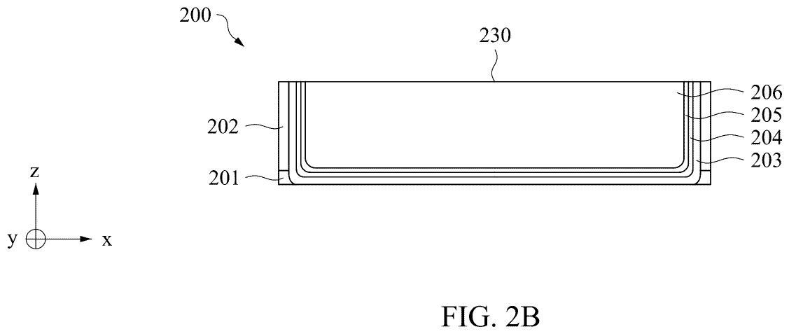

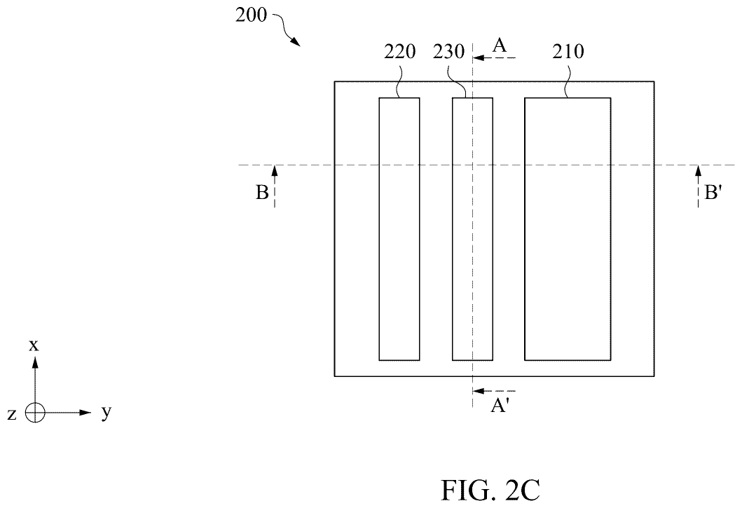

FIG. 1 illustrates a process flow 100 of manufacturing a semiconductor device according to embodiments of the disclosure. FIGS. 2A, 2B, and 2C show sectional views of a process stage of a sequential operation of manufacturing a semiconductor device according to embodiments of the disclosure. The structure 200 as shown in FIG. 2A, FIG. 2B, and FIG. 2C is illustrated in operation S110. FIG. 2C shows a top view of the structure 200. FIG. 2A shows a cross-sectional view of the structure 200 cut along the BB′ plane as shown in FIG. 2C. FIG. 2B shows a cross-sectional view of the structure 200 cut along the AA′ plane as shown in FIG. 2C.

In some embodiments, the structure 200 is a semiconductor substrate layer, which includes a substrate 201. The substrate 201 may include all underlying layers, devices, junctions, and other features.

In some embodiments, a dielectric layer 202 is deposited on a top surface of the substrate 201. In some examples, the dielectric layer 202 is a silicon oxide layer.

In some embodiments, the structure 200 further includes a plurality of metal interconnect features (e.g., 210, 220, and/or 230) embedded in the structure 200. In some embodiments, the plurality of metal interconnect features (e.g., 210, 220, and/or 230) are formed by a procedure including lithography, etching, and deposition. In some embodiments, the plurality of metal interconnect features (e.g., 210, 220, and/or 230) is an electrode of a capacitor, a resistor, or a portion of a resistor. Alternatively, the plurality of metal interconnect features (e.g., 210, 220, and/or 230) may be a doped region (such as a source or a drain), or a gate electrode (such as a metal gate of a FinFET). In some embodiments, the plurality of metal interconnect features (e.g., 210, 220, and/or 230) is a silicide feature disposed on the respective source, drain, or gate.

In some embodiments, as shown in FIG. 2C, the plurality of metal interconnect features (e.g., 210, 220, and/or 230) include a first metal interconnect feature 210 extending along the x-direction, a second metal interconnect feature 220 extending along the x-direction, and a third metal interconnect feature 230 extending along the x-direction. The x-direction is a leak non-critical direction. In some embodiments, the plurality of metal interconnect features (e.g., 210, 220, and/or 230) are equally spaced from each other along the y-direction. The y-direction, which is perpendicular to the x-direction, is a leak-critical direction. The z-direction is perpendicular to the x-direction and the y-direction. In some embodiments, the plurality of metal interconnect features (e.g., 210, 220, and/or 230) are formed by suitable techniques in the dielectric layer 202. The plurality of metal interconnect features (e.g., 210, 220, and/or 230) may be in electrical contact with the substrate 201 including any or all the underlying layers, devices, junctions, and/or other features in the substrate 201.

In some embodiments, as shown in FIG. 2A, the first metal interconnect feature 210 has a width W₁ and the second metal interconnect feature 220 has a width W₂ along the y-direction. In some embodiments, W₁ is greater than W₂.

In some embodiments, as shown in FIG. 2A, a width of the third metal interconnect feature 230 along the y-direction equals the width W₂ of the second metal interconnect feature 220.

In some embodiments, as shown in FIG. 2A and FIG. 2B, each of the plurality of metal interconnect features (e.g., 210, 220, and/or 230) includes a metal layer 206. For example, the metal layer 206 includes aluminum (Al), copper (Cu), tungsten (W), combinations thereof, and/or the like. In some embodiments, the metal layer 206 is further surrounded by a barrier layer 203. The barrier layer 203 may prevent diffusion of the metal layer 206 and provide material adhesion for the metal layer 206. The barrier layer 203 may include titanium nitride (TiN), tantalum nitride (TaN), tungsten nitride (WN), titanium silicon nitride (TiSiN), tantalum silicon nitride (TaSiN), combinations thereof, and/or the like. In some examples, a thickness of the barrier layer 203 is in a range from about 0.1 nm to about 4 nm. In some examples, the thickness of the barrier layer 203 is in a range from about 0.3 nm to about 2 nm.

In some embodiments, each of the plurality of metal interconnect features (e.g., 210, 220, and/or 230) further include a first liner 204 and a second liner 205 formed between the metal layer 206 and the barrier layer 203. In some embodiments, the first liner 204 is formed on the barrier layer 203, and the second liner 205 is subsequently on the first liner 204.

In some embodiments, the first liner 204 is a cobalt (Co) layer. In some examples, a thickness of the first liner 204 is in a range from about 0.05 nm to about 2 nm. In some examples, the thickness of the first liner 204 is in a range from about 0.1 nm to about 1 nm.

In some embodiments, the second liner 205 is a ruthenium (Ru) layer. In some examples, a thickness of the second liner 205 is in a range from about 0.05 nm to about 2 nm. In some examples, the thickness of the second liner 205 is in a range from about 0.1 nm to about 1 nm.

It should be noted that while FIGS. 2A, 2B, and 2C illustrate a portion of the structure 200 from the cross-sectional views and the top view of the structure 200, one of ordinary skill in the art would recognize many variations, alternatives, and modifications.

Referring back to FIG. 1, in some embodiments, a cobalt (Co) layer is deposited on the plurality of metal interconnect features in operation S120 using suitable deposition techniques.

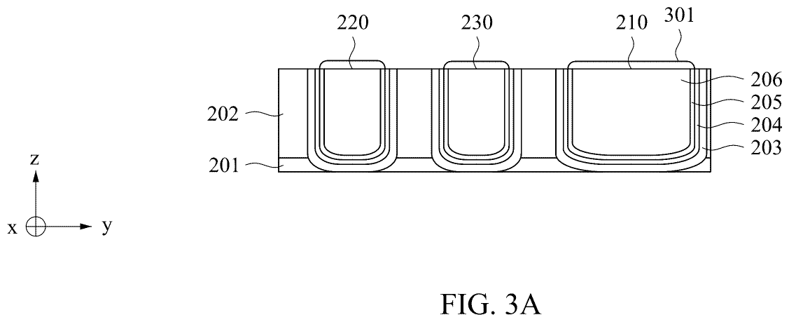

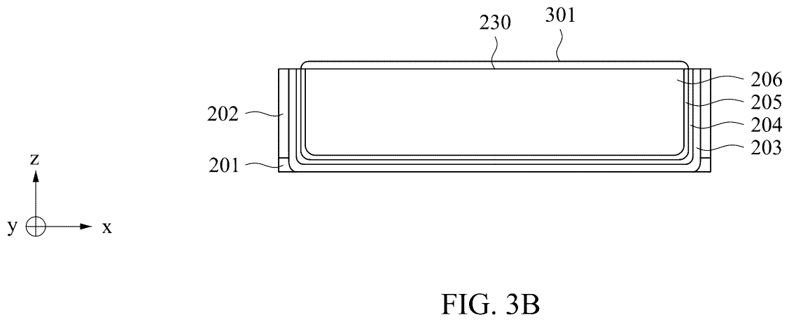

FIGS. 3A and 3B show sectional views of a process stage of forming a cap layer in a sequential operation according to embodiments of the disclosure.

As shown in FIG. 3A and FIG. 3B, the cap layer 301 is deposited on the first metal interconnect feature 210, the second metal interconnect feature 220, and the third metal interconnect feature 230. In some embodiments, the cap layer 301 is made of cobalt. In some embodiments, the cobalt layer 301 covers the metal layer 206 of the plurality of metal interconnect features (e.g., 210, 220, and/or 230). In some examples, the cobalt layer 301 is a raised cap layer, which covers only the first metal interconnect feature 210, the second metal interconnect feature 220, and/or the third metal interconnect feature 230.

In some embodiments, a thickness of the cobalt layer 301 is in a range from about 0.2 nm to about 5 nm. In some embodiments, the thickness of the cobalt layer 301 is in a range from about 0.5 nm to about 3 nm, such that the contact resistance (Rc) of the bottom self-aligned vias can be minimized, thereby the performance of the semiconductor device is improved. In some examples, if the thickness of the cobalt layer 301 is greater than 5 nm, the bottom self-aligned via formed later would be deeper, and thus, harder to be fully filled. In some examples, if the thickness of the cobalt layer 301 is smaller than 0.2 nm, the cobalt layer 301 would provide insufficient leakage prevention between the via layer and the metal layer. If the thickness of the cobalt layer is greater than the disclosed ranges the layer may be unnecessarily thick and may not offer any improvement in leakage prevention while increasing the manufacturing cost of the semiconductor devices.

Referring back to FIG. 1, in some embodiments, a first etching stop layer 401 is subsequently formed on the cap layer or cobalt layer 301 and the dielectric layer 202 in operation S130. In some embodiments, the cap layer 301 is made of a material having a different etch selectivity to certain etching solutions than the first etching stop layer 401. In some embodiments, the cap layer 301 has a higher selectivity to an etching solution having a pH in a range from about 5 to about 6.8.

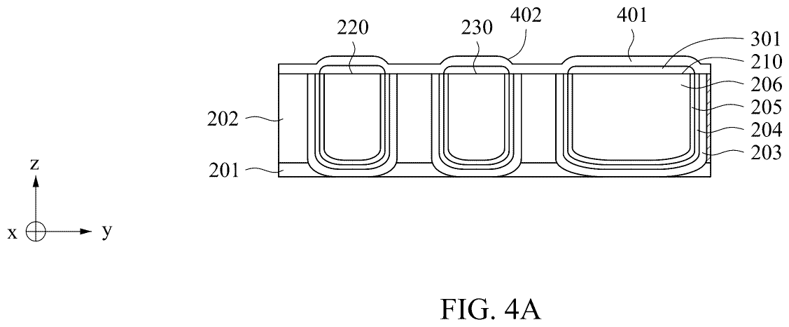

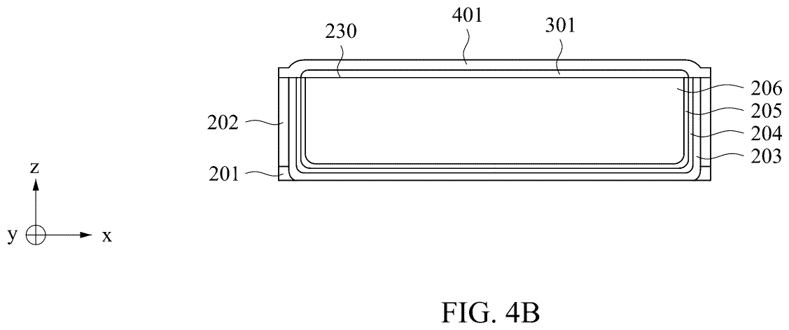

FIGS. 4A and 4B show sectional views of a process stage of forming the first etching stop layer in a sequential operation according to embodiments of the disclosure.

As shown in FIG. 4A and FIG. 4B, a first etching stop layer 401 is deposited on the cobalt layer 301 and the dielectric layer 202. In some embodiments, the first etching stop layer 401 is conformally formed on the cobalt layer 301 and the dielectric layer 202. For example, the first etching stop layer 401 covers the cobalt layer 301 and a portion of the top surface of the dielectric layer 202 exposed by the cobalt layer 301.

In some embodiments, the first etching stop layer 401 has a step structure 402 around the edges of the cobalt layer 301. For example, the step structure 402 confines the bottom critical dimension of a later formed bottom self-aligned via, such that the risk of the bottom self-aligned via becoming shorted to the neighboring third metal interconnect feature 230 is reduced and leakage of current between the second metal interconnect feature 220 and the neighboring third metal interconnect feature 230 is prevented.

In some embodiments, the first etching stop layer 401 is an aluminum-based etching stop layer. For example, the first etching stop layer 401 is an aluminum nitride (AlN) layer in some embodiments. In other embodiments, the first etching stop layer 401 is an aluminum oxynitride (AlON) layer, an aluminum oxide (Al₂O₃) layer, combinations thereof, and/or the like. In some embodiments, the first etching stop layer 401 is a hafnium oxide (HfOₓ) layer, a zirconium oxide (ZrOₓ) layer, combinations thereof, and/or the like.

In some embodiments, a thickness of the first etching stop layer 401 is in a range from about 0.2 nm to about 5 nm. In some embodiments, the thickness of the first etching stop layer 401 is in a range from about 0.5 nm to about 3 nm.

Referring back to FIG. 1, in some embodiments, a low-k dielectric layer having via trenches is formed on the cobalt layer 301 and the dielectric layer 202 in operation S140.

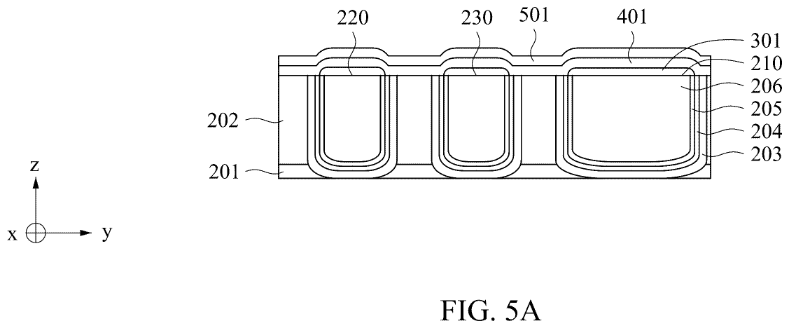

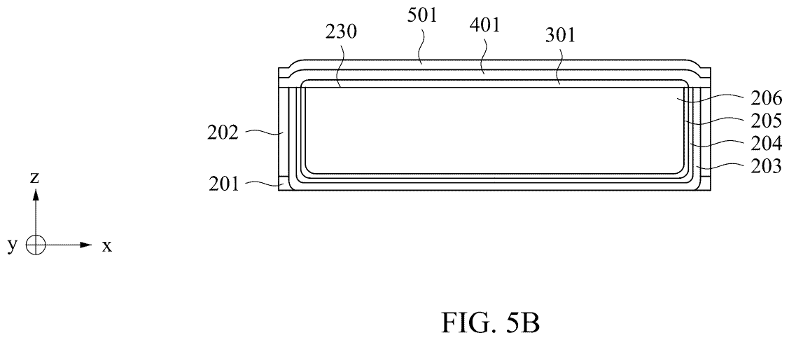

FIGS. 5A and 5B show sectional views of a process stage of forming a second etching stop layer in a sequential operation according to embodiments of the disclosure.

In some embodiments, as shown in FIG. 5A and FIG. 5B, before forming the low-k dielectric layer, a second etching stop layer 501 is subsequently formed on the first etching stop layer 401. For example, a second etching stop layer 501 is conformally formed on the first etching stop layer 401. In some examples, the second etching stop layer 501 is a SiOC-based etching stop layer. In some embodiments, the second etching stop layer 501 is deposited using any suitable technique, such as a chemical vapor deposition (CVD) process, a physical vapor deposition (PVD) process, an atomic layer deposition (ALD) process, or an epitaxial growing process. In some embodiments, the second etching stop layer 501 includes an oxide layer including carbon, oxygen, silicon, other suitable materials, or combinations thereof.

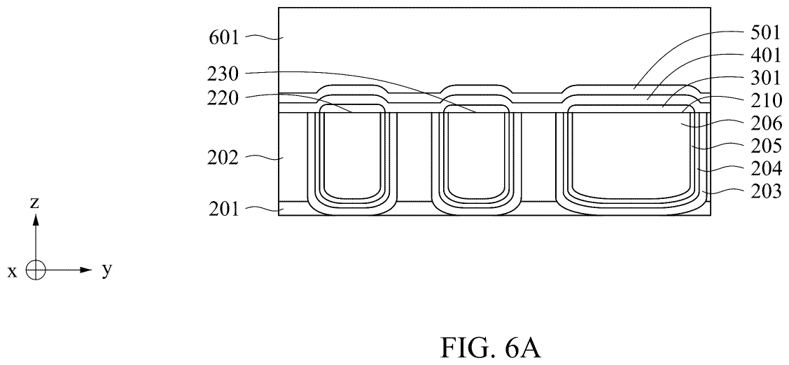

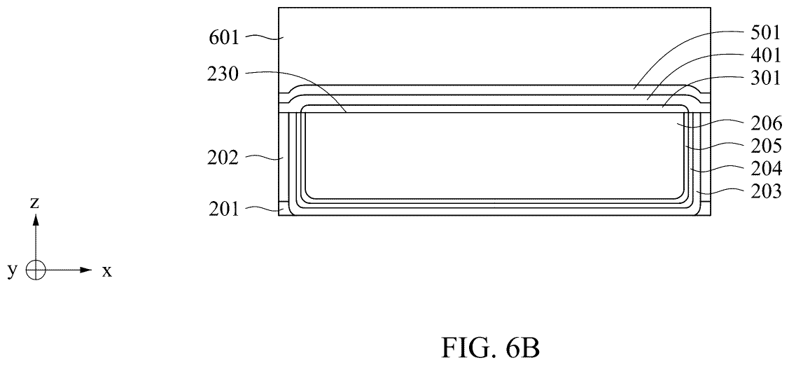

FIGS. 6A and 6B show sectional views of a process stage of forming a low-k dielectric layer in a sequential operation according to embodiments of the disclosure.

In some embodiments, as shown in FIG. 6A and FIG. 6B, the low-k dielectric layer 601 is subsequently formed on the second etching stop layer 501. In some examples, the second etching stop layer 501 has a lower etching rate in comparison with the low-k dielectric layer 601 in a subsequent etching process to form via trenches in the low-k dielectric layer 601.

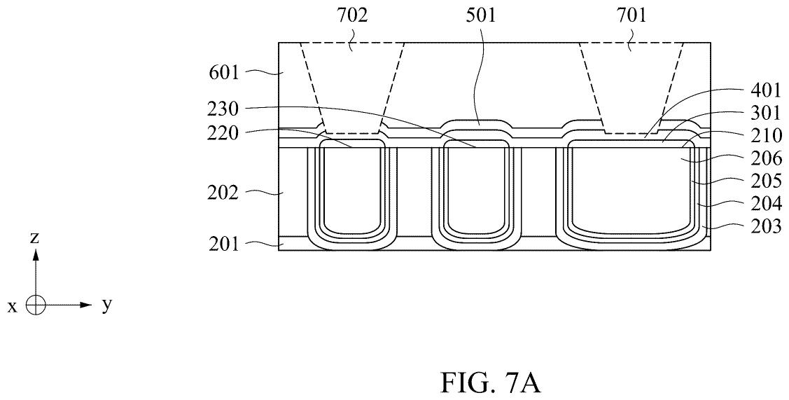

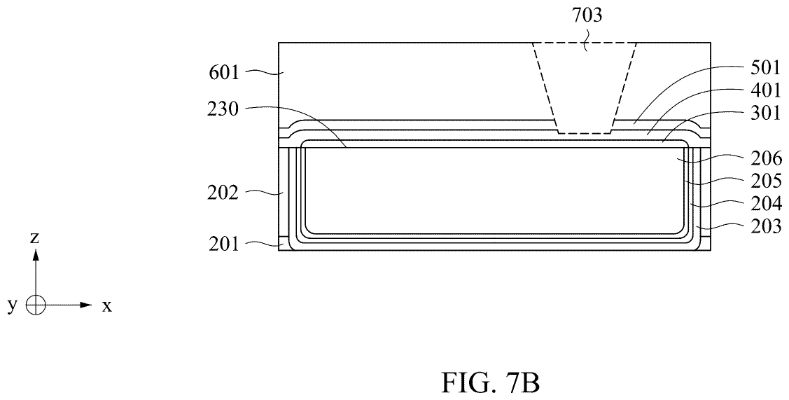

FIGS. 7A and 7B show sectional views of a process stage of forming the via trenches in the low-k dielectric layer 601 of a sequential operation according to embodiments of the disclosure.

As shown in FIG. 7A and FIG. 7B, in some embodiments, the low-k dielectric layer 601 and the second etching stop layer 501 are subsequently etched by a first etching process to form the via trenches (e.g., 701, 702, and/or 703). In some examples, the first etching process etches through the low-k dielectric layer 601, and the second etching stop layer 501. The first etching process may stop at the first etching stop layer 401. For example, a first via trench 701 is formed by the first etching process to expose a portion of the first etching stop layer 401 on the top surface of the first metal interconnect feature 210. In another example, a second via trench 702 is formed by the first etching process to expose a portion of the first etching stop layer 401 on the top surface of the second metal interconnect feature 220. In another example, a third via trench 703 is formed by the first etching process to expose a portion of the first etching stop layer 401 on the top surface of the third metal interconnect feature 230.

In some embodiments, the first etching process is any suitable etching process, such as a plasma dry etching. In some embodiments, the first etching process uses a CHₓF_{y}, CFₓ, Cl₂, or BCl₃-based plasma.

In some embodiments, before performing the first etching process, a mask for the first etching process is formed on top of the low-k dielectric layer 601 to transfer a designed pattern corresponding to the plurality of metal interconnect features (e.g., 210, 220, and/or 230) to the low-k dielectric layer 601. In some embodiments, the mask is removed after the first etching process is performed.

Referring back to FIG. 1, in some embodiments, bottom self-aligned vias (BSAVs) are formed by etching the first etching stop layer 401 and the cobalt layer 301 to expose the metal interconnect features in operation S150.

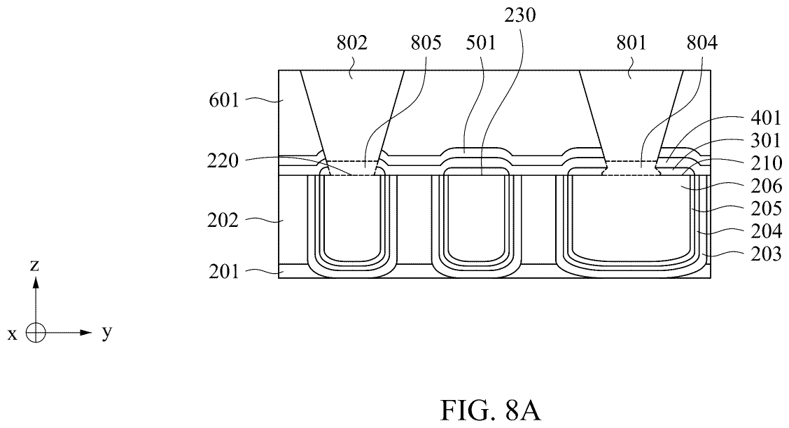

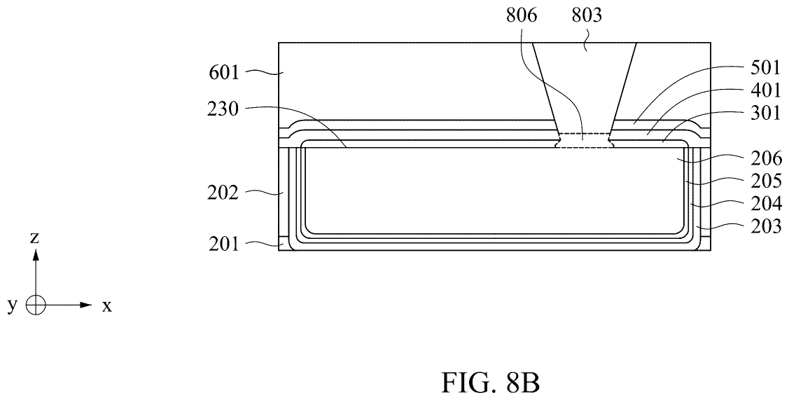

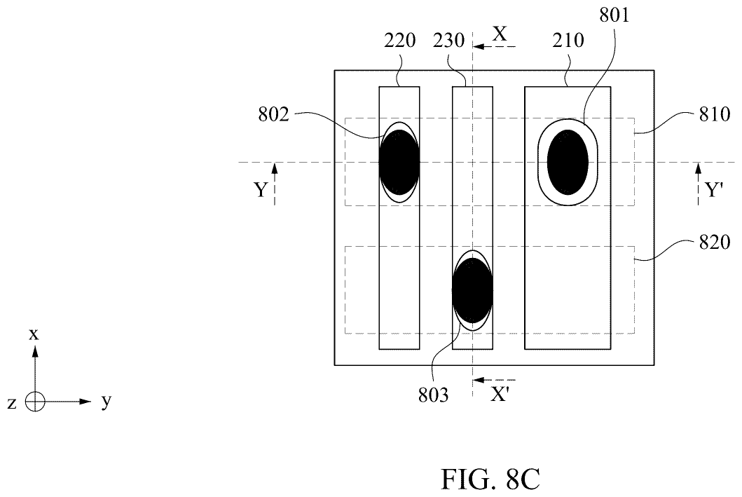

FIGS. 8A, 8B, and 8C show sectional views and a top view of a process stage of forming the bottom self-aligned vias (e.g., 801, 802, and/or 803) in a sequential operation according to embodiments of the disclosure. FIG. 8C shows a top view of the bottom self-aligned vias (e.g., 801, 802, and/or 803). FIG. 8A shows a cross-sectional view of the bottom self-aligned vias (e.g., 801, 802, and/or 803) cut along the YY′ plane as shown in FIG. 8C. FIG. 8B shows a cross-sectional view of the bottom self-aligned vias (e.g., 801, 802, and/or 803) cut along the XX′ plane as shown in FIG. 8C.

In some embodiments, as shown in FIG. 8A, FIG. 8B and FIG. 8C, the first etching stop layer 401 and the cobalt layer 301 are subsequently etched by a second etching process to form the bottom self-aligned vias (e.g., 801, 802, and/or 803). In some examples, the second etching process etches downward through the first etching stop layer 401 and the cobalt layer 301. The second etching process may stop at the plurality of metal interconnect features (e.g., 210, 220, and/or 230). For example, a first bottom self-aligned via 801 is formed by the second etching process to expose the top surface of the first metal interconnect feature 210. In another example, a second bottom self-aligned via 802 is formed by the second etching process to expose the top surface of the second metal interconnect feature 220. In another example, a third bottom self-aligned via 803 is formed by the second etching process to expose the top surface of the third metal interconnect feature 230.

In some embodiments, the second etching process is a wet etching process, in which a chemical solution is applied to the first etching stop layer 401 and the cobalt layer 301.

In some embodiments, the chemical solution includes a hydrofluoric acid (HF) based cleaning solution, a solvent-based cleaning solution, any combinations thereof, and/or the like.

In some embodiments, the first etching stop layer 401 is an aluminum-based etching stop layer. In some embodiments, the etching selectivity of the cobalt layer 301 and the first etching stop layer 401 are adjusted by using an etching solution having a specific range of pH values. For example, the pH value of the chemical solution is in a range from about 5 to about 6.8. In some examples, the cobalt etching rate is increased to improve the etching selectivity of cobalt over the aluminum-based etching stop layer.

In some embodiments, as shown in FIG. 8C, the first bottom self-aligned via 801 has an oval shape in the top view. In some embodiments, as shown in FIG. 8C, the second bottom self-aligned via 802 has an oval shape in the top view. In some embodiments, as shown in FIG. 8C, the third bottom self-aligned via 803 has an oval shape in the top view.

For illustration purposes, as shown in FIG. 8C, top metal interconnect features (e.g., 810 and/or 820) extending in the y-direction are shown on top of the bottom self-aligned vias (e.g., 801, 802, and/or 803). The area where the top metal interconnect features (e.g., 810 and/or 820) cross over the metal interconnect features (e.g., 210, 220, and/or 230) may confine the critical dimensions of the bottom self-aligned vias (e.g., 801, 802, and/or 803) in the x-direction and the y-direction.

In some embodiments, as shown in FIG. 8A, along the leak critical y-direction, the first bottom self-aligned via 801 has an enlarged critical dimension at the bottom of the bottom self-aligned via 801. In some embodiments, as shown in FIG. 8C, along the leak non-critical x-direction, the first bottom self-aligned via 801 also has an enlarged critical dimension. In other words, the critical dimensions of the bottom self-aligned via over the wider metal interconnect feature (e.g., 210 is wider than 220 in the y-direction) have enlarged critical dimensions in both the leak non-critical x-direction and the leak critical y-direction.

In some embodiments, as shown in FIG. 8A and FIG. 8C, the second bottom self-aligned via 802 only has an enlarged critical dimension along the leak non-critical x-direction at the bottom of the bottom self-aligned via 802.

In some embodiments, as shown in FIG. 8B, along the leak non-critical x-direction, the third bottom self-aligned via 803 has an enlarged critical dimension at the bottom of the bottom self-aligned via 803. In other words, the critical dimensions of the bottom self-aligned via over the second metal interconnect feature 220 have enlarged critical dimensions only along the leak non-critical x-direction.

Alternatively, in some embodiments, the first bottom self-aligned via 801 has a round shape in the top view. In some embodiments, the second bottom self-aligned via 802 has a round shape in the top view. In some embodiments, the third bottom self-aligned via 803 has a round shape in the top view.

In some embodiments, as shown in FIG. 8A, the first bottom self-aligned via 801 has an hourglass-shaped profile. For example, the first bottom self-aligned via 801 has an enlarged bottom portion 804. In some embodiments, as shown in FIG. 8B, the third bottom self-aligned via 803 has an hourglass-shaped profile. For example, the third bottom self-aligned via 803 has an enlarged bottom portion 806.

One advantageous feature of having the bottom self-aligned vias with enlarged bottom portions, as shown in FIG. 8A and FIG. 8B, is that the enlarged bottom portions help to reduce the contact resistance (Rc) of the bottom self-aligned vias, thereby improving the performance of the semiconductor device. Another advantageous feature of having the bottom self-aligned vias with enlarged bottom portions, as shown in FIG. 8A and FIG. 8B, is that the enlarged bottom portions confine the bottom critical dimension (CD) of the bottom self-aligned vias to be aligned to the top critical dimension of the corresponding metal interconnect feature. This can improve the tolerance to the variations of the critical dimension of the bottom self-aligned vias and the requirements for the overlay control. Consequently, the leakage margin can be improved, thereby enlarging the process window for manufacturing the semiconductor devices.

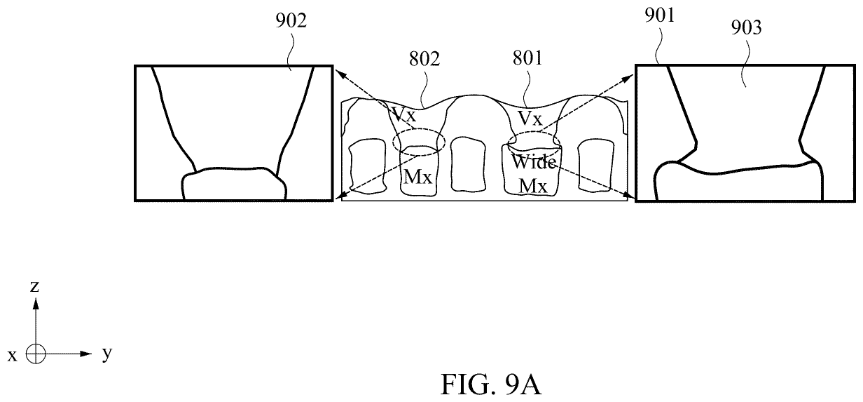

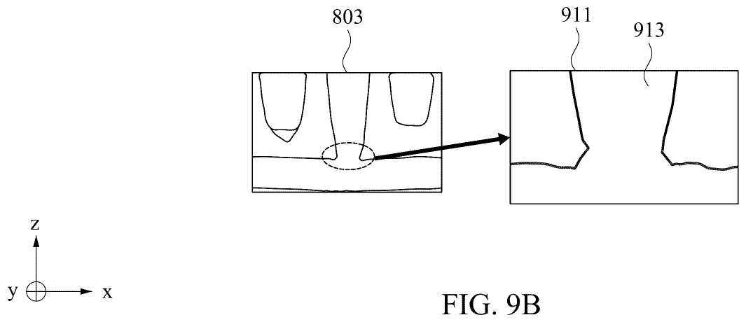

FIG. 9A shows an example of the vias along the y direction according to embodiments of the disclosure.

As shown in FIG. 9A, a close-up view 901 of the first bottom self-aligned via 801 and a close-up view 902 of the second bottom self-aligned via 802 are illustrated. In some embodiments, as illustrated in the close-up view 901, the first bottom self-aligned via 801 has an hourglass-shaped profile 903. In other words, the first bottom self-aligned via 801 has an enlarged critical dimension along the y direction. In some embodiments, as illustrated in the close-up view 902, the second bottom self-aligned via 802 does not have an enlarged critical dimension along the y direction.

FIG. 9B shows an example of the bottom self-aligned vias along the x direction according to embodiments of the disclosure.

As shown in FIG. 9B, a close-up view 911 of the third bottom self-aligned via 803 is illustrated. In some embodiments, as illustrated in the close-up view 911, the third bottom self-aligned via 803 has an hourglass-shaped profile 913. In other words, the third bottom self-aligned via 803 has an enlarged critical dimension along the x direction.

FIG. 10 shows an example of the bottom self-aligned vias along the y direction according to embodiments of the disclosure.

As shown in FIG. 10, a close-up view 1001 of the first bottom self-aligned via 801 is illustrated. In some embodiments, as illustrated in the close-up view 1001, the first bottom self-aligned via 801 has an hourglass-shaped profile 903. For example, each sidewall 1002 of the hourglass-shaped profile 903 has a first sidewall portion 1002a and a second sidewall portion 1002b.

In some embodiments, the first sidewall portion 1002a and the second sidewall portion 1002b meet at an interface between the first etching stop layer 401 and the cobalt layer 301.

The first sidewall portion 1002a forms an angle A with a waist plane 1004 of the first metal interconnect feature 210. The second sidewall portion 1002b forms an angle B with the top surface 1003 of the first metal interconnect feature 210. In some embodiments, angle A is in a range from about 95° to about 140°. In some embodiments, angle A is in a range from about 100° to about 125°. In some embodiments, angle B is in a range from about 30° to less than about 90°. In some embodiments, angle B is in a range from about 45° to about 75°. At angles outside the disclosed ranges there may be insufficient protection from current leakage or the contact resistance Rc may be too high.

As shown in FIG. 10, the hourglass-shaped profile 903 has the waist plane 1004, where the first sidewall portion 1002a and a second sidewall portion 1002b meet. In some embodiments, the waist plane 1004 is located where the first etching stop layer 401 and the cobalt layer 301 meet. In some embodiments, the hourglass figure is formed by the difference in etch selectivity of the first etching stop layer 401 and the cobalt layer 301 or by adjusting the parameters of the etching solution when etching the first etching stop layer 401 and the cobalt layer. In some embodiments, an etching solution having a pH range of about 5 to about 6.8 is used when etching the cobalt layer 301. Such an etching solution provides higher Co to etching stop layer selectivity.

A distance between the waist plane 1004 and the top surface 1005 of the low-k dielectric layer 601, defined by the thickness h₁, is controlled by the thickness of the low-k dielectric layer 601. In some embodiments, h₁ is in a range from about 16 nm to about 50 nm. A distance between the waist plane 1004 and the top surface 1003 of the first metal interconnect feature 210, defined by the thickness h₂, is controlled by the thickness of the cobalt layer 301. In some embodiments, h₂ is in a range from about 1 nm to about 6 nm.

In some embodiments, a ratio between h₁ and h₂ is in a range from about 2.67 to about 50. For example, as the ratio between h₁ and h₂ gets smaller, the contact resistance (Rc) of the bottom self-aligned via 801 becomes smaller. At ratios outside the disclosed ranges there may be insufficient protection from current leakage or the contact resistance Rc may be too high.

The width of the first bottom self-aligned via 801, 803 decreases from a top surface of the low-k dielectric layer 601 to a minimum width at the waist plane 1004 and then the width of the bottom portion of the self-aligned via 801, 803 increases from waist plane 1004 through the cobalt layer 301 to the metal layer.

In some embodiments, as shown in FIG. 10, a critical dimension d₁ of the bottom self-aligned via 801 along the waist plane 1004 is smaller than a critical dimension d₂ of the bottom self-aligned via 801 along the top surface 1003 of the first metal interconnect feature 210.

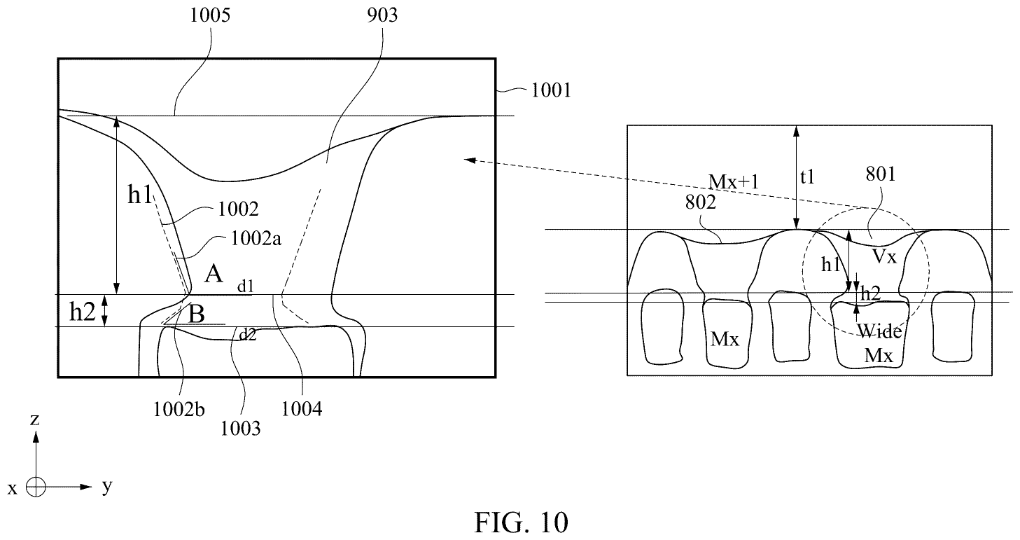

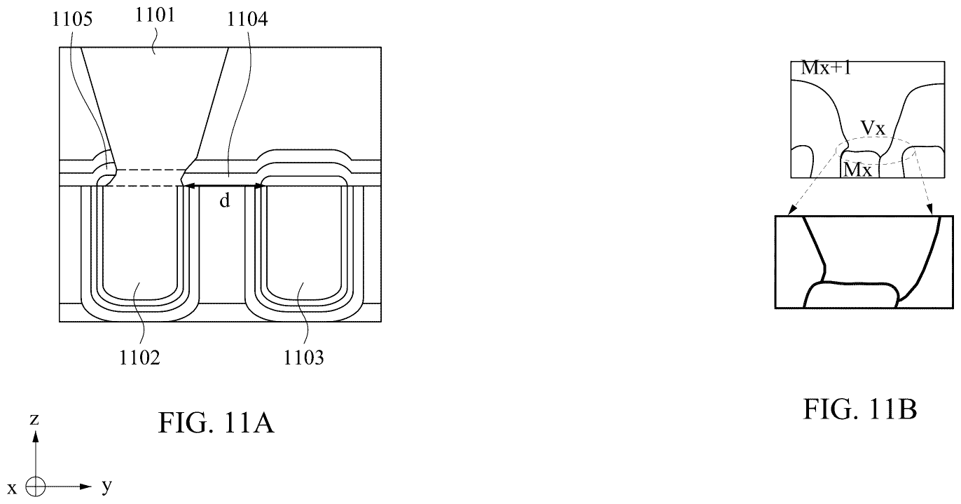

FIG. 11A and FIG. 11B show an example of the bottom self-aligned vias according to embodiments of the disclosure.

As shown in FIG. 11A and FIG. 11B, in some embodiments, the bottom self-aligned via 1101 formed on top of a metal interconnect feature 1102 is shifted in the y direction due to lithography-alignment variations. For example, the bottom self-aligned via 1101 is shifted several nanometers in the y direction. However, the aluminum nitride layer (the first etching stop layer) 1104 has a step structure 1105 around the edges of the cobalt layer, and as a result, the bottom critical dimension of the bottom self-aligned via 1101 is confined by the step structure 1105. FIG. 11B is a detailed view of FIG. 11A, illustrating that the bottom critical dimension of the bottom self-aligned via 1101 shrinks at the bottom of the bottom self-aligned via 1101. Therefore, the risk of the bottom self-aligned via 1101 shorting to a neighboring metal interconnect feature 1103 is reduced and the leakage current between the metal interconnect feature 1102 and the neighboring metal interconnect feature 1103 is prevented.

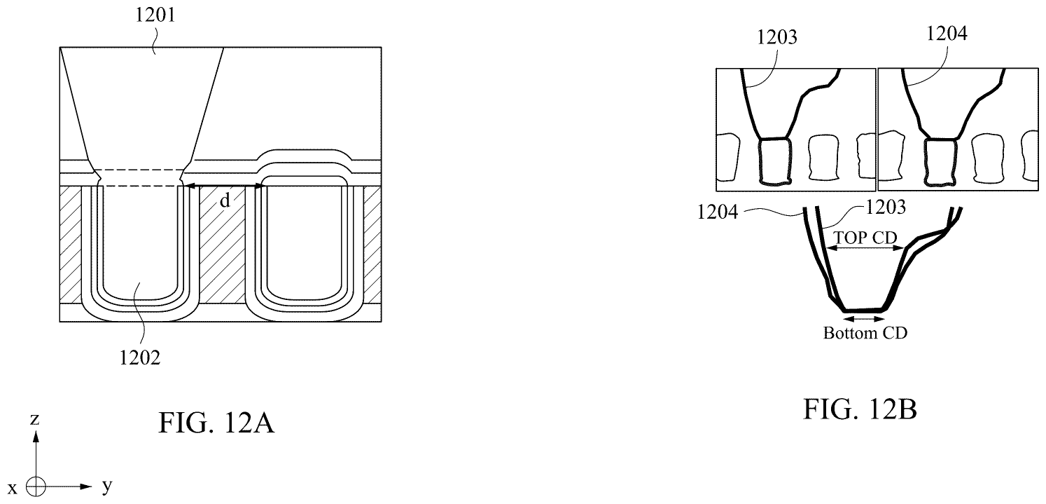

FIGS. 12A and 12B show an example of the bottom self-aligned vias according to embodiments of the disclosure.

As shown in FIG. 12A and FIG. 12B, in some embodiments, the bottom self-aligned via 1201 formed on top of a metal interconnect feature 1202 is aligned with the bottom self-aligned via 1202. In some embodiments, the bottom self-aligned via 1201 has a first profile 1203, as shown in FIG. 12B, after a first dry etching process. For example, a top critical dimension (CD) of the profile 1203 is 14.6 nm, and a bottom critical dimension of the profile 1203 is 11.4 nm. In some embodiments, the bottom self-aligned via 1201 has a second profile 1204 after a first dry etching process, thereby enlarging the top critical dimension. For example, the top critical dimension (CD) of the second profile 1204 is 17.7 nm, and a bottom critical dimension of the second profile 1204 is 12.2 nm. As illustrated by the bottom comparison between first profile 1203 and the second profile 1204 in FIG. 12B, the top critical dimension of the profile 1203 is enlarged by 3.1 nm by the first dry etching process, while the bottom critical dimension of the profile 1203 is enlarged by 0.8 nm. Accordingly, the bottom critical dimension is significantly less sensitive to the first dry etching variation than the top critical dimension. That is, the bottom self-aligned via helps reduce the bottom critical dimension sensitivity to the dry etching process for enlarging the top critical dimension. As a result, the bottom self-aligned via has improved tolerance to the variations of the critical dimension and the overlay. Consequently, the leakage margin and the process window are improved.

In some embodiments, a conductive metal layer (not shown in FIG. 8A, FIG. 8B, or FIG. 8C) is formed in the bottom self-aligned vias (e.g., 801, 802, and/or 803) to provide an electric connection between the plurality of metal interconnect features (e.g., 210, 220, and/or 230) and other semiconductor devices that are subsequently formed on top of the bottom self-aligned vias (e.g., 801, 802, and/or 803). The other semiconductor devices may include an electrode of a capacitor, a resistor, or a portion of a resistor, a doped region (such as a source or a drain), a gate electrode (such as a metal gate of a FinFET), and/or a silicide feature disposed on the respective source, drain, or gate. The conductive metal layer may be made of conductive materials including aluminum (Al), copper (Cu), tungsten (W), respective alloys, combinations thereof, and/or other suitable conductive materials.

The novel self-aligned via structure and the manufacturing methods according to the present disclosure provide an improved bottom self-aligned via structure and methods of forming the same thereby reducing the contact resistance and preventing current leakage and electrical shorting than conventional techniques and configurations. Embodiments of the disclosure provide an improved bottom self-aligned via structure that improves the tolerance to the variations of the critical dimension of the bottom self-aligned vias. Consequently, the leakage margin can be improved, thereby enlarging the process window for manufacturing the semiconductor devices.

An embodiment of the disclosure is a method of manufacturing a semiconductor device, including providing a semiconductor substrate layer including a metal interconnect feature embedded in the semiconductor substrate layer, and depositing a liner layer on the metal interconnect feature. The method further includes depositing an etching stop layer on the liner layer and the semiconductor substrate layer and forming a dielectric layer on the etching stop layer with a via trench to expose the etching stop layer. The method also includes etching the etching stop layer and the liner layer to form a via structure to expose the metal interconnect feature, wherein the via structure has an hourglass-shaped profile. In an embodiment, the metal interconnect feature extends in a first direction, and the via structure has an enlarged bottom critical dimension along a second direction, wherein the first direction is perpendicular to the second direction. In an embodiment, the via structure has an enlarged bottom critical dimension along the first direction. In an embodiment, the etching stop layer is an aluminum-based etching stop layer. In an embodiment, the liner layer is a cobalt (Co) layer, and a thickness of the cobalt layer is in a range from 0.5 nm to 3 nm. In an embodiment, the semiconductor substrate layer further comprises a barrier layer and a substrate, wherein the barrier layer is formed between the metal interconnect feature and the substrate. In an embodiment, the hourglass-shaped profile has a waist plane, a distance between the waist plane and a top surface of the dielectric layer is a first distance, a distance between the waist plane and a top surface of the metal interconnect feature is a second distance, and a ratio between the first distance and the second distance is in a range from 2.67 to 50. In an embodiment, the first distance is in a range from 16 nm to 50 nm, and the second distance is in a range from 1 nm to 6 nm. In an embodiment, the etching stop layer and the liner layer are etched by a wet etching process using a chemical solution with a pH value in a range from 5 to 6.8. In an embodiment, a bottom critical dimension of the via structure is less sensitive to the first dry etching variation than a top critical dimension of the via structure. In an embodiment, a sidewall of the hourglass-shaped profile has a first sidewall portion above the waist plane and a second sidewall portion below the waist plane, and the first sidewall portion forms a first angle with the top surface of the metal interconnect feature, and the second sidewall portion forms a second angle with the top surface of the metal interconnect feature 210, wherein the first angle is in a range from 95° to 140° and the second angle is in a range from 30° to less than 90°.

Another embodiment of the disclosure is a method of manufacturing a semiconductor device, including providing a semiconductor substrate layer including a metal interconnect feature embedded in the semiconductor substrate layer, and depositing a liner layer on the metal interconnect feature. The method further includes depositing an etching stop layer on the liner layer and the semiconductor substrate layer, wherein the etching stop layer has a step structure at an edge of the liner layer and forming a dielectric layer on the etching stop layer with a via trench to expose the etching stop layer. The method also includes etching the etching stop layer and the liner layer to form a via structure 801/802/803 to expose the metal interconnect feature. In an embodiment, wherein the via structure has an hourglass-shaped profile. In an embodiment, the hourglass-shaped profile has a waist plane, a distance between the waist plane and a top surface of the dielectric layer is a first distance, a distance between the waist plane and a top surface of the metal interconnect feature is a second distance, and a ratio between the first distance and the second distance is in a range from 2.67 to 50. In an embodiment, the first distance is in a range from 16 nm to 50 nm, and the second distance is in a range from 1 nm to 6 nm. In an embodiment, the liner layer is a cobalt (Co) layer, and the etching stop layer and the cobalt layer to form the via structure are etched by a wet etching process using a chemical solution with a pH value in a range from 5 to 6.8. In an embodiment, a bottom critical dimension of the via structure is less sensitive to the first dry etching variation than a top critical dimension of the via structure.

Another embodiment of the disclosure is a semiconductor device, including a semiconductor substrate layer including a metal interconnect feature embedded in the semiconductor substrate layer, and a liner layer on the metal interconnect feature. The semiconductor device further includes an etching stop layer on the liner layer and the semiconductor substrate layer, and a dielectric layer on the etching stop layer. The semiconductor device also includes a via structure through the dielectric layer, the etching stop layer, and the liner layer exposing the metal interconnect feature, wherein the via structure has an hourglass-shaped profile. In an embodiment, the hourglass-shaped profile has a waist plane, a distance between the waist plane and a top surface of the dielectric layer is a first distance, a distance between the waist plane and a top surface of the metal interconnect feature is a second distance, and a ratio between the first distance and the second distance is in a range from 2.67 to 50. In an embodiment, the etching stop layer has a step structure at an edge of the liner layer.

An embodiment of the disclosure is a method of manufacturing a semiconductor device, including providing a semiconductor substrate layer including a first metal interconnect feature and a second metal interconnect feature extending in a first direction and embedded in the semiconductor substrate layer. The first metal interconnect feature is wider than the second metal interconnect feature along a second direction, and the first direction is perpendicular to the first direction; depositing a liner layer on the first metal interconnect feature and the second metal interconnect feature. The method further includes depositing an etching stop layer on the liner layer and the semiconductor substrate layer and forming a dielectric layer on the etching stop layer with via trenches to expose the etching stop layer. The method also includes etching the etching stop layer and the liner layer to form via structures to expose the first metal interconnect feature and the second metal interconnect feature, where each of the via structures has an hourglass-shaped profile.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
providing a semiconductor substrate layer including a metal interconnect feature embedded in the semiconductor substrate layer;
depositing a liner layer on the metal interconnect feature;
depositing an etching stop layer on the liner layer and the semiconductor substrate layer;
forming a dielectric layer on the etching stop layer with a via trench to expose the etching stop layer; and
etching the etching stop layer and the liner layer to form a via structure to expose the metal interconnect feature, wherein the via structure has an hourglass-shaped profile.

2. The method according to claim 1, wherein:
the metal interconnect feature extends in a first direction, and
the via structure has an enlarged bottom critical dimension along a second direction, wherein the first direction is perpendicular to the first direction.

3. The method according to claim 2, wherein:
the via structure has an enlarged bottom critical dimension along the first direction.

4. The method according to claim 1, wherein:
the etching stop layer is an aluminum-based etching stop layer.

5. The method according to claim 1, wherein:
the liner layer is a cobalt (Co) layer, and
a thickness of the cobalt layer is in a range from 0.5 nm to 3 nm.

6. The method according to claim 1, wherein:
the semiconductor substrate layer further comprises a barrier layer and a substrate, wherein the barrier layer is formed between the metal interconnect feature and the substrate.

7. The method according to claim 1, wherein:
the hourglass-shaped profile has a waist plane,
a distance between the waist plane and a top surface of the dielectric layer is a first distance,
a distance between the waist plane and a top surface of the metal interconnect feature is a second distance, and
a ratio between the first distance and the second distance is in a range from 2.67 to 50.

8. The method according to claim 7, wherein:
the first distance is in a range from 16 nm to 50 nm, and
the second distance is in a range from 1 nm to 6 nm.

9. The method according to claim 7, wherein:
the etching stop layer and the liner layer are etched by a wet etching process using a chemical solution with a pH value in a range from 5 to 6.8.

10. The method according to claim 9, wherein:
a bottom critical dimension of the via structure is less sensitive to the first dry etching variation than a top critical dimension of the via structure.

11. The method according to claim 7, wherein:
a sidewall of the hourglass-shaped profile has a first sidewall portion above the waist plane and a second sidewall portion below the waist plane, and
the first sidewall portion forms a first angle with the top surface of the metal interconnect feature, and the second sidewall portion forms a second angle with the top surface of the metal interconnect feature 210, wherein the first angle is in a range from 95° to 140° and the second angle is in a range from 30° to less than 90°.

12. A method of forming a semiconductor device, comprising:
providing a semiconductor substrate layer including a metal interconnect feature embedded in the semiconductor substrate layer;
depositing a liner layer on the metal interconnect feature;
depositing an etching stop layer on the liner layer and the semiconductor substrate layer, wherein the etching stop layer has a step structure at an edge of the liner layer;
forming a dielectric layer on the etching stop layer with a via trench to expose the etching stop layer; and
etching the etching stop layer and the liner layer to form a via structure to expose the metal interconnect feature.

13. The method according to claim 12, wherein:
wherein the via structure has an hourglass-shaped profile.

14. The method according to claim 13, wherein:
the hourglass-shaped profile has a waist plane,
a distance between the waist plane and a top surface of the dielectric layer is a first distance,
a distance between the waist plane and a top surface of the metal interconnect feature is a second distance, and
a ratio between the first distance and the second distance is in a range from 2.67 to 50.

15. The method according to claim 14, wherein:
the first distance is in a range from 16 nm to 50 nm, and
the second distance is in a range from 1 nm to 6 nm.

16. The method according to claim 14, wherein:
the liner layer is a cobalt (Co) layer, and
the etching stop layer and the cobalt layer to form the via structure are etched by a wet etching process using a chemical solution with a pH value in a range from 5 to 6.8.

17. The method according to claim 16, wherein:
a bottom critical dimension of the via structure is less sensitive to the first dry etching variation than a top critical dimension of the via structure.

18. A semiconductor device, comprising:
a semiconductor substrate layer including a metal interconnect feature embedded in the semiconductor substrate layer;
a liner layer on the metal interconnect feature;
an etching stop layer on the liner layer and the semiconductor substrate layer;
a dielectric layer on the etching stop layer; and
a via structure through the dielectric layer, the etching stop layer, and the liner layer exposing the metal interconnect feature, wherein the via structure has an hourglass-shaped profile.

19. The semiconductor device according to claim 18, wherein:
the hourglass-shaped profile has a waist plane,
a distance between the waist plane and a top surface of the dielectric layer is a first distance,
a distance between the waist plane and a top surface of the metal interconnect feature is a second distance, and
a ratio between the first distance and the second distance is in a range from 2.67 to 50.

20. The semiconductor device according to claim 18, wherein:
the etching stop layer has a step structure at an edge of the liner layer.
